(19) United States
(12) Patent Application Publication
(10) Pub. No.: US 2021/0410305 A1
(43) Pub. Date: Dec. 30, 2021

(54) FOLDABLE MECHANISM AND FOLDABLE DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventor: Zikang FENG, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/639,762

(22) PCT Filed: Dec. 24, 2019
(86) PCT No.: PCT/CN2019/127698

§ 371 Date: Feb. 18, 2020

(30) Foreign Application Priority Data
Dec. 13, 2019 (CN) 201911278564.0

(51) Int. Cl. H05K 5/02; H05K 5/00

(52) U.S. Cl. CPC H05K 5/0226; H04M 1/0268; H05K 5/0017

(57) ABSTRACT

A foldable mechanism and a foldable display device including the same are provided. The foldable mechanism includes a bending component configured to fold and unfold between 0 degrees and 180 degrees, wherein the bending component has a first surface and a second surface opposite to each other; a supporting component disposed on the first surface of the bending component, including a first elastic material layer and a flexible metal layer, wherein the first elastic material layer connects the bending component and the flexible metal layer is disposed on a surface of the first elastic material layer away from the bending component; and a connecting component disposed on the second surface of the bending component, including a second elastic material layer.

### FIELD OF INVENTION

The invention relates to a foldable electronic device, and particularly to a foldable mechanism and a foldable display device using the foldable mechanism.

### BACKGROUND

Portable electronic devices such as mobile phones, media players, smart watches, car displays, and tablet computers are becoming more common these days. These devices often comprise foldable display devices. Users often want the smallest device that can be conveniently placed in a pocket or purse or worn on the hand, but also want a larger display surface for easier viewing. Therefore, manufacturers have begun to develop flexible displays for use in smaller portable electronic devices to provide larger display surfaces.

However, a bending portion of the flexible display of a conventional foldable display device is usually completely adhered to a case of the device. However, when the bending portion of the foldable display device completely adhered to the case is bent or folded, compressive stress caused by a difference in inner diameter between the flexible display and the case may cause the bending portion to protrude inward and be separated therefrom. Therefore, the flexible display of the conventional foldable display device often encounters undesirable problems such as cracking and peeling when it is bent or folded.

Therefore, it is necessary to provide a foldable mechanism to solve the problems encountered by existing foldable display devices.

### Technical Problem

The bending portion of the flexible display of a conventional foldable display device is usually fully adhered to the case of the device. However, when a bending portion of the foldable display device completely adhered to the case is bent or folded, compressive stress caused by a difference in inner diameter between the flexible display and the case may cause the bending portion to protrude inward and separate therefrom. Therefore, the flexible display of the conventional foldable display device often encounters undesirable problems such as cracking and peeling when it is bent or folded.

### Technical Solution

In view of this, the present invention provides a foldable mechanism to solve the problems that the flexible display of the foldable display device in the prior art which encounters cracking and peeling when it is bended or folded.

To achieve the above purpose of the present invention, one embodiment of present invention provides a foldable mechanism, comprising a bending component configured to fold and unfold between 0 degrees and 180 degrees, wherein the bending component has a first surface and a second surface opposite to each other; a supporting component disposed on the first surface of the bending component, comprising a first elastic material layer and a flexible metal layer, wherein the first elastic material layer connects the bending component and the flexible metal is disposed on a surface of the first elastic material layer away from the bending component; and a connecting component disposed on the second surface of the bending component, comprising a second elastic material layer.

In one embodiment, the bending component comprise a plurality of rigid body blocks; a metal sheet; a plurality of fixed shafts; a plurality of first connecting rods; a plurality of second connecting rods; a plurality of third connecting rods; and a plurality of pulleys respectively assembled on the third connecting rods. The metal sheet is disposed on one surface of the plurality of rigid body blocks and comprises a bendable and recoverable metal material. The plurality of fixed shafts are respectively disposed at two opposite surfaces of the plurality of rigid body blocks to which the metal sheet is not connected The plurality of first connecting rods and the plurality of second connecting rods are alternately connected to a fixed shaft of an adjacent rigid body block to rotate relatively. The plurality of third connecting rods are respectively fixed to the fixed shafts on the plurality of rigid body blocks on the outermost sides. The plurality of third connecting rods are longer than the plurality of first connecting rods and the plurality of second connecting rods, and there is no relative displacement and rotation between the plurality of third connecting rods and the plurality of fixed shafts. The bonding component is folded and unfolded between 0 degrees and 180 degrees by the connection and combination of the plurality of rigid body blocks, the plurality of fixed shafts, the plurality of first connecting rods, the plurality of second connecting rods, and the plurality of third connecting rods.

In one embodiment, the first elastic material layer is connected to the metal sheet of the bending component and has a same shape as the metal sheet.

In one embodiment, the first elastic material layer has a Young's modulus of 0.1 to 100 Mpa, and the second elastic material layer has a Young's modulus of 0.1 to 100 Mpa.

In one embodiment, the metal sheet has a tensile strength between 100 and 1000 MPa.

Moreover, another embodiment of the present invention provides a foldable display device, comprising a bending component configured to fold and unfold between 0 degrees and 180 degrees, wherein the bending component has a first surface and a second surface opposite to each other; a supporting component disposed on the first surface of the bending component, comprising a first elastic material layer and a flexible metal layer, wherein the first elastic material layer connects the bending component and the flexible metal is disposed on a surface of the first elastic material layer away from the bending component; a connecting component disposed on the second surface of the bending component, comprising a second elastic material layer; and a flexible display disposed on a surface of the supporting component away from the bending component to support the flexible metal layer, wherein two ends of the flexible display are curved and respectively cover the bending component.

In one embodiment, the bending component of the foldable display device of the present invention comprises a plurality of rigid body blocks; a metal sheet; a plurality of fixed shafts; a plurality of first connecting rods; a plurality of second connecting rods; a plurality of third connecting rods; and a plurality of pulleys respectively assembled on the third connecting rods. The metal sheet is disposed on one surface of the plurality of rigid body blocks and comprises a bendable and recoverable metal material. The plurality of fixed shafts are respectively disposed at two opposite surfaces of the plurality of rigid body blocks to which the metal sheet is not connected. The plurality of first connecting rods and the plurality of second connecting rods are alternately connected to a fixed shaft of an adjacent rigid body block to rotate relatively. The plurality of third connecting rods are respectively fixed to the fixed shafts on the plurality of rigid body blocks on the outermost sides. The plurality of third connecting rods are longer than the plurality of first connecting rods and the plurality of second connecting rods, and there is no relative displacement and rotation between the plurality of third connecting rods and the plurality of fixed shafts. The bonding component is folded and unfolded between 0 degrees and 180 degrees by the connection and combination of the plurality of rigid body blocks, the plurality of fixed shafts, the plurality of first connecting rods, the plurality of second connecting rods, and the plurality of third connecting rods.

In one embodiment, the first elastic material layer is connected to the metal sheet of the bending component and has a same shape as the metal sheet.

In one embodiment, the first elastic material layer has a Young's modulus of 0.1 to 100 Mpa, and the second elastic material layer has a Young's modulus of 0.1 to 100 Mpa.

In one embodiment, the metal sheet has a tensile strength between 100 and 1000 MPa.

### Advantageous Effects

Compared with the prior art, the foldable mechanism of the present invention can use elasticity of an elastic material layer to compensate for dimensional difference caused by a change in size of an inner surface between the bending mechanism and a flexible display during the folding and unfolding of the bending mechanism. A foldable display device of the present invention realizes folding and unfolding operations of foldable electronic products through a flexible display equipped with a foldable mechanism similar to a pulley, so that problems including cracking and peeling due to damages to flexible displays during bending and folding can be resolved. In addition, the elastic material layer connected to the flexible display in the unfolded state of the flexible display has a preset tensile force, which can relieve problems such as unevenness of the bent area after the flexible display is bent.

### BRIEF DESCRIPTION OF DRAWINGS

To detailly explain the technical schemes of the embodiments or existing techniques, drawings that are used to illustrate the embodiments or existing techniques are provided. Apparently, the illustrated embodiments are just a part of those of the present disclosure. It is easy for any person having ordinary skill in the art to obtain other drawings without labor for inventiveness.

FIG. 1 is an exploded schematic view of a foldable display device according to a first embodiment of the present invention.

FIG. 2 is a schematic perspective view of the foldable display device according to the first embodiment of the present invention in a flattened state.

FIG. 3 is a schematic side view of the foldable display device according to the first embodiment of the present invention in the flattened state.

FIG. 4 is a schematic perspective view of the foldable display device according to the first embodiment of the present invention in a folded state.

FIG. 5 is a schematic side view of the foldable display device according to the first embodiment of the present invention in the folded state.

FIG. 6 is a schematic side view of a foldable display device in a flattened state according to a second embodiment of the present invention.

FIG. 7 is a schematic side view of the foldable display device according to the second embodiment of the present invention in a folded state.

FIG. 8 is a schematic perspective view of the foldable display device according to the second embodiment of the present invention in the folded state.

### DETAILED DESCRIPTION

The following descriptions of the embodiments are with reference to the attached drawings to illustrate specific embodiments in which the present invention can be implemented. Furthermore, the directional terms mentioned in the present invention include, for example, top, bottom, top, bottom, front, back, left, right, inside, outside, side, periphery, center, horizontal, horizontal, vertical, vertical, axial, The radial direction, the uppermost layer, or the lowermost layer, etc., are only directions referring to the attached drawings. Therefore, the directional terms used are for explaining and understanding the present invention, but not for limiting the present invention.

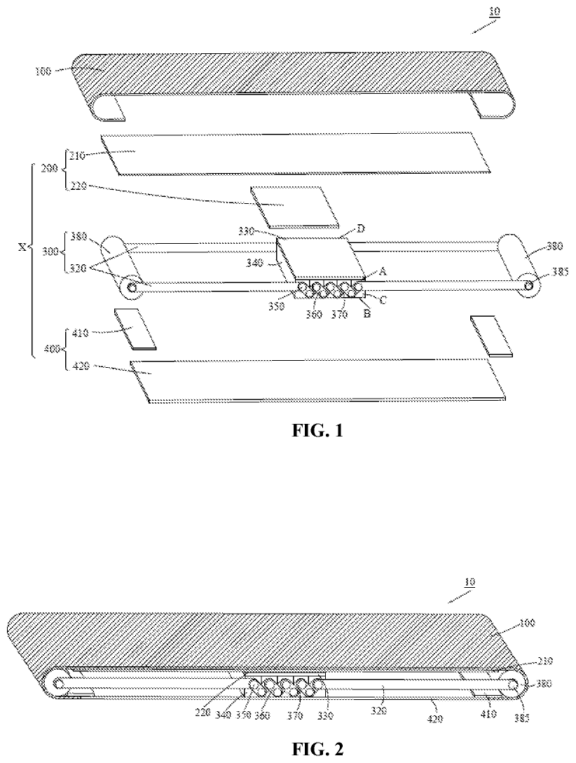

FIG. 1 is an exploded schematic view of a foldable display device 10 according to a first embodiment of the present invention. In this embodiment, the foldable display device 10 comprises a flexible display 100, a supporting component 200, a bending component 300, and a connecting component 400.

As shown in FIG. 1, the bending component 300 is, for example, a hinge component comprising an odd number of rigid body blocks 340, a metal sheet 330, a plurality of fixed shafts 350, a plurality of first connecting rods 360, a plurality of second connecting rods 370, and several third connecting rods 320. In this embodiment, the bending component 300 comprises, for example, five rigid body blocks 340 as shown in FIG. 1, but the number of rigid body blocks 340 can be adjusted according to actual folding requirements and is not limited to that shown in FIG. 1.

The plurality of rigid body blocks 340 each have a surface A facing the flexible display 100 and a surface B facing the connecting component 400, and the plurality of fixed shafts 350 are disposed at opposite surfaces C and D of the plurality of rigid body blocks 340 not connected to the metal sheet 330. The plurality of rotatable first connecting rods 360 and the plurality of second connecting rods 370 are arranged on the fixed shafts 350 of adjacent rigid body blocks 340, and the plurality of first connecting rods 360 and the second connecting rods 370 are alternately connected and fixed to the fixed shafts 350, and they are relatively rotatable. The third connecting rods 320 are respectively fixed to the fixed shafts 350 on the outermost rigid body block 340. The third connecting rods 320 are longer than the first connecting rods 360 and the second connecting rods 370, and there is no relative displacement and rotation between the third connecting rods 320 and the fixed shafts 350. The other end of the third connecting rods 320 is disposed on a pulley 380 having a fixed shaft 385 at both ends, and the third connecting rods 320 and the pulley 380 can rotate relative to each other. With the connection and combination of the plurality of rigid body blocks 340, the fixed shafts 350, the first connecting rods 360, the second connecting rods 370, and the third connecting rods 320, the bending component 300 can be folded and unfolded from 0 degree (folded) to 180 degrees (unfolded).

In an embodiment, a material of the rigid body blocks 340 is, for example, an aluminum alloy of 6 series or more, stainless steel, nickel-plated alloy, or hard plastic, and has a thickness of 1 to 10 mm. A material of the metal sheet 330 is, for example, stainless steel, amorphous crystalline, titanium steel, or copper, and has a thickness of 0.1 to 5 mm and a tensile strength of 100 to 1000 megapascals (MPa) to provide suitable bending and recovery abilities.

The bending component 300 has a first surface and a second surface opposite to each other. The supporting component 200 is disposed on the first surface (as described above) of the bending component 300 to support the flexible display 100, and it comprises a flexible metal layer 210 and a first elastic material layer 220. A material of the flexible metal layer 210 is, for example, stainless steel, amorphous crystalline, titanium steel, or copper, which has a certain strength and can be bent and restored. Its size is similar to that of the bending component 300 below, and has a thickness of 0.01 to 0.05 mm. The first elastic material layer 220 is an elastic material having a Young's modulus of 0.1 to 100 MPa, such as rubber or silicone. A shape of the first elastic material layer 220 is same as the metal sheet 330 in the lower bending component 300, while its size is similar to the metal sheet 330 in the lower bending component 300 and has a thickness between 0.1-5 mm.

The flexible display 100 is disposed on a surface (for example, an upper surface) of the supporting component 200 away from the bending component 300. The flexible display 100 may be a liquid crystal display (LCD), an organic light emitting diode (OLED) display, or other flexible screens having flexibility. The flexible display 100 may or may not have a touch function. As shown in FIG. 1, two ends of the flexible display 100 are curved and respectively cover two pulleys 380 in the bending component 300. Therefore, the flexible display 100 has a portion extending to the surface B of the rigid body blocks 340 facing the connection component 400.

The connecting component 400 is disposed on the second surface (as follows) of the bending component 300, and it comprises a second elastic material layer 420 and two connecting components 410. A size of the second elastic material layer 420 is slightly smaller than the bending component 300 formed above, and has a thickness between 0.1 and 1 mm. The second elastic material layer 420 is a good elastic material with a preset tensile force of Young's modulus of 1-100 Mpa, such as rubber. A material of the plurality of connecting components 410 is, for example, rubber, silicone, or plastic, and has a thickness between 0.2 and 3 mm. The connecting components 410 can be connected to the flexible display 100 and the second elastic material layer 420 by, for example, binding or hot pressing.

The supporting component 200, the bending component 300, and the connecting component 400 shown in FIG. 1 are connected in order from top to bottom to form the foldable mechanism X of the first embodiment of the present invention. The foldable mechanism X and the flexible display 100 connected in order from top to bottom form the foldable display device 10 of the first embodiment of the present invention. In the foldable display device 10 shown in FIG. 1, after the flexible display 100 is assembled to the pulley 380, the two ends of the flexible display 100 and the second elastic material layer 420 are connected through a connecting component 410 to assemble a structure similar to a pulley, and the operation of the bending component 300 allows the foldable display device 10 to be switched from a folded state to an unfolded state.

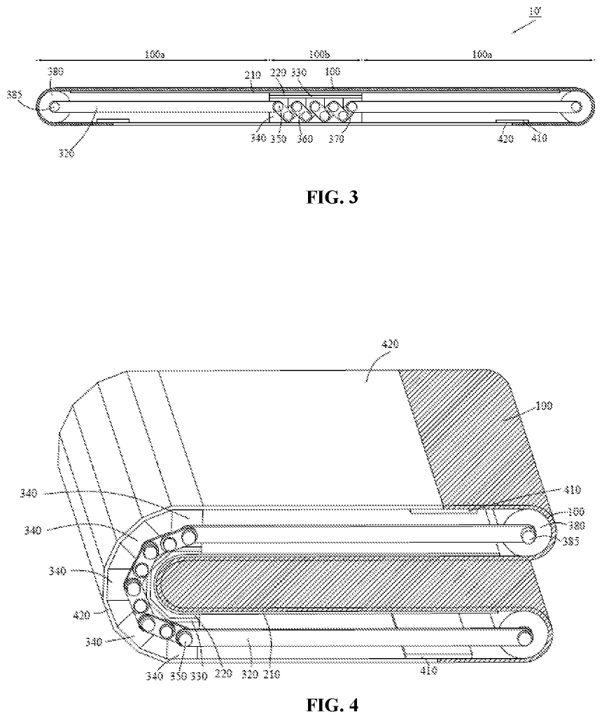

FIG. 2 shows a schematic perspective view of the foldable display device 10 shown in FIG. 1 in an unfolded state, and FIG. 3 shows a schematic side view of the foldable display device 10 shown in FIG. 1 in an unfolded state. In FIGS. 2-3, the same reference numerals show the same components as those of the foldable display device 10 of FIG. 1.

As shown in FIGS. 2-3, the flexible display 100 of the foldable display device 10 is defined with two separate non-bending areas 100a and a bending area 100b located between the two non-bending areas 100a. The bending area 100b is generally located above the plurality of rigid body blocks 304 and the metal sheet 330 of the bending component 300, and is an area where the bending component 300 is bended when repeatedly operating between folded and unfolded states. The metal sheet 330 has an effect of supporting the flexible display 100 to improve its stiffness. The plurality of non-bending areas 100a does not have the plurality of rigid body blocks 304 below. Therefore, when the bending component 300 is switching between folded and unfolded states, an outline of the flexible display 100 remains unchanged without being bended. Because the flexible display 100 is in contact with the second elastic material layer 420 and forms a pulley structure with the pulley 310, the second elastic material layer 420 has a preset tensile force in the unfolded state, helping the flexible display 100 to recover after bending and keeping it unfolded. The part of flexible display 100 in the bending area 100 is connected to the bending component 300 through the flexible metal layer 210 and the first elastic material layer 220, which prevents left and right offsets of the flexible display 100 from being folded and unfolded during folding and unfolding operations.

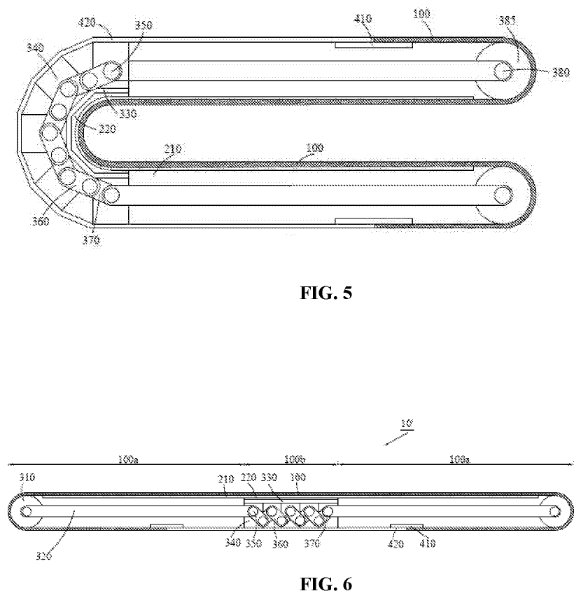

FIG. 4 shows a schematic perspective view of the foldable display device 10 shown in FIGS. 1-3 in a folded state, and FIG. 5 shows a schematic side view of the foldable display device 10 shown in FIGS. 1-3 in a folded state. In FIGS. 4-5, the same reference numerals show the same components as those of the foldable display device 10 of FIG. 1.

As shown in FIGS. 4-5, the display surfaces of the flexible displays 100 in the two non-bending areas 100a in the foldable display device 10 are bent inwardly toward each other by the operation of the foldable mechanism X in the bending component 300. In the folded state, the dimensions of the first connecting rod 360 and the second connecting rod 370 can be calculated by setting the dimensions of the first connecting rod 360 and the second connecting rod 370 to bend the bending component 300 when all the first connecting rods 360 and the second connecting rods 370 that are mated with each other are on a same straight line. Five rigid body blocks 304 inside can be evenly distributed and rotated from 0 to 45 degrees, so that the entire bending component 300 is bent exactly to 180 degrees, so that the foldable display device 10 exhibits 180 degrees bending. The rigid blocks 340 are connected to the bendable and recoverable metal sheet 330. During the bending process, an included angle between two rigid body blocks will become larger and larger, until the first connecting rod 360 and the second connecting rod 370 reach the same straight line, and the included angle between the adjacent rigid blocks 340 reaches the maximum limit.

As shown in FIG. 4, after the display surface of the flexible display 100 in the two non-bending areas 100a of the foldable display device 10 is bent in the opposite direction to show a 180-degree fold, the flexible display 100 is curved and wrapped. The two ends of the surface 310 covering the pulley 310 in the bending component 300 and extending to the surface B of the rigid body block 340 facing the display connection assembly 400 are exposed, which can be used to display information such as time, weather, and reminder messages.

In the foldable display device 10 shown in FIGS. 1-6, except that the portion of the flexible display 100 and the bending component 300 in the bending portion 100b cannot slide relative to the bending component 300, the remaining parts are not connected to the bending component 300 and can slide relative to the bending component 300, so the elasticity of the second elastic material layer 420 can be used to compensate for changes in size difference in the inner surface between the bending component 300 and the flexible display 100 during the folding and unfolding of the bending component 300. The foldable display device 10 is equipped with a flexible display 100 through a foldable mechanism X similar to a pulley to realize the folding and unfolding operation of a foldable electronic product such as a mobile phone. This can solve problems including cracking and peeling due to damages to the flexible display 100 when it is bent and folded.

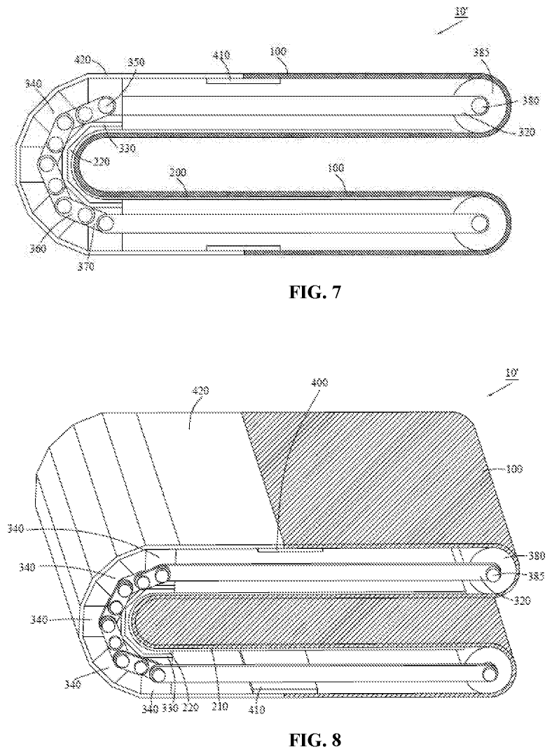

FIG. 6 is a schematic side view of a foldable display device 10′ according to a second embodiment of the present invention in an unfolded state. FIG. 7 is a schematic side view of the foldable display device 10′ according to the second embodiment of the present invention in a folded state. FIG. 8 is a schematic perspective view of the foldable display device 10′ according to the second embodiment of the present invention in the folded state. In FIGS. 6-8, the same reference numerals show the same components as those of the foldable display device 10 of FIGS. 1-5.

Different from the previous embodiments, in this embodiment, by increasing a deflection of the flexible display 100 of the foldable display device 10′ and covering the pulley 310 in the bending component 300 and extending to the rigid body block 340 to face the display connecting component 400, the area of the two exposed end portions of the surface B makes its setting position extend more toward the rigid body block 340. In this way, the flexible display 100 of the foldable display device 10′ in the two non-bending areas 100a is bent inward toward each other, and both ends of the flexible display 100 are flexed to cover the pulley 310 in the bending component 300 and a portion of the surface B that extends to the rigid body block 340 facing the display connection component 400 is increased in size at this time, and can be used as a folded outer screen of a folding display device 10′, such as a foldable mobile phone.

While the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

What is claimed is:

1. A foldable mechanism, comprising:
a bending component configured to fold and unfold between 0 degrees and 180 degrees, wherein the bending component has a first surface and a second surface opposite to each other;
a supporting component disposed on the first surface of the bending component, comprising a first elastic material layer and a flexible metal layer, wherein the first elastic material layer connects the bending component and the flexible metal layer is disposed on a surface of the first elastic material layer away from the bending component; and
a connecting component disposed on the second surface of the bending component, comprising a second elastic material layer.

2. The foldable mechanism according to claim 1, wherein the bending component comprises:
a plurality of rigid body blocks;
a metal sheet;
a plurality of fixed shafts;
a plurality of first connecting rods;
a plurality of second connecting rods;
a plurality of third connecting rods; and
a plurality of pulleys respectively assembled on the third connecting rods, wherein:
the metal sheet is disposed on one surface of the plurality of rigid body blocks and comprises a bendable and recoverable metal material;
the plurality of fixed shafts are respectively disposed at two opposite surfaces of the plurality of rigid body blocks to which the metal sheet is not connected;
the plurality of first connecting rods and the plurality of second connecting rods are alternately connected to a fixed shaft of an adjacent rigid body block to rotate relatively;
the plurality of third connecting rods are respectively fixed to the fixed shafts on the plurality of rigid body blocks on outermost sides;
the plurality of third connecting rods are longer than the plurality of first connecting rods and the plurality of second connecting rods, and there is no relative displacement and rotation between the plurality of third connecting rods and the plurality of fixed shafts; and
the bonding component is folded and unfolded between 0 degrees and 180 degrees by connection and combination of the plurality of rigid body blocks, the plurality of fixed shafts, the plurality of first connecting rods, the plurality of second connecting rods, and the plurality of third connecting rods.

3. The foldable mechanism according to claim 2, wherein the first elastic material layer is connected to the metal sheet of the bending component and has a same shape as the metal sheet.

4. The foldable mechanism according to claim 2, wherein the first elastic material layer has a Young's modulus of 0.1 to 100 Mpa, and the second elastic material layer has a Young's modulus of 0.1 to 100 Mpa.

5. The foldable mechanism according to claim 2, wherein the metal sheet has a tensile strength between 100 and 1000 MPa.

6. A foldable display device, comprising:
a bending component configured to fold and unfold between 0 degrees and 180 degrees, wherein the bending component has a first surface and a second surface opposite to each other;
a supporting component disposed on the first surface of the bending component, comprising a first elastic material layer and a flexible metal layer, wherein the first elastic material layer connects the bending component and the flexible metal layer is disposed on a surface of the first elastic material layer away from the bending component;
a connecting component disposed on the second surface of the bending component, comprising a second elastic material layer; and
a flexible display disposed on a surface of the supporting component away from the bending component to support the flexible metal layer, wherein two ends of the flexible display are curved and respectively cover the bending component.

7. The foldable display device according to claim 6, wherein the bending component comprises:
a plurality of rigid body blocks;
a metal sheet;
a plurality of fixed shafts;
a plurality of first connecting rods;
a plurality of second connecting rods;
a plurality of third connecting rods; and
a plurality of pulleys respectively assembled on the third connecting rods;
wherein the metal sheet is disposed on one surface of the plurality of rigid body blocks and comprises a bendable and recoverable metal material;
the plurality of fixed shafts are respectively disposed at two opposite surfaces of the plurality of rigid body blocks to which the metal sheet is not connected;
the plurality of first connecting rods and the plurality of second connecting rods are alternately connected to a fixed shaft of an adjacent rigid body block to rotate relatively;
the plurality of third connecting rods are respectively fixed to the fixed shafts on the plurality of rigid body blocks on outermost sides;
the plurality of third connecting rods are longer than the plurality of first connecting rods and the plurality of second connecting rods, and there is no relative displacement and rotation between the plurality of third connecting rods and the plurality of fixed shafts; and
the bonding component is folded and unfolded between 0 degrees and 180 degrees by connection and combination of the plurality of rigid body blocks, the plurality of fixed shafts, the plurality of first connecting rods, the plurality of second connecting rods, and the plurality of third connecting rods.

8. The foldable display device according to claim 7, wherein the first elastic material layer is connected to the metal sheet of the bending component and has a same shape as the metal sheet.

9. The foldable display device according to claim 7, wherein the first elastic material layer has a Young's modulus of 0.1 to 100 Mpa, and the second elastic material layer has a Young's modulus of 0.1 to 100 Mpa.

10. The foldable display device according to claim 7, wherein the metal sheet has a tensile strength between 100 and 1000 MPa.
